(19) United States
(12) Patent Application Publication
(10) Pub. No.: US 2023/0018414 A1
(43) Pub. Date: Jan. 19, 2023

(54) Retiming and Overclocking of Large Circuits

(71) Applicant: Intel Corporation, Santa Clara, CA (US)

(72) Inventors: Martin Langhammer, Alderbury (GB); Gregg William Baeckler, San Jose, CA (US); Sergey Vladimirovich Gribok, Santa Clara, CA (US); Mahesh A. Iyer, Fremont, CA (US)

(21) Appl. No.: 17/956,565

(22) Filed: Sep. 29, 2022

(51) Int. Cl. G06F 1/08; H03K 19/17736

(52) U.S. Cl. CPC G06F 1/08; H03K 19/1774

(57) ABSTRACT

The present disclosure describes techniques for incorporating pipelined DSP blocks or other types of embedded functions into a logic circuit with a slower clock rate without any clock crossing complexities, and at the same time managing the power consumption of the more complex design that results from it. The techniques include generating a faster clock or several faster clocks that may have a faster clock rate than the clock used by the logic circuit and that may be used as clock input to the embedded pipelined DSP blocks. In addition, the present disclosure describes techniques for generating, improving, and using the faster clock to sample the output of a logic circuit using pulses of generated faster clock, which may allow to increase the clock frequency of the circuit to an optimal level, while maintaining functional correctness.

### BACKGROUND

The present disclosure relates generally to integrated circuit (IC) devices such as programmable logic devices (PLDs). Particularly, the present disclosure relates to using multiple circuit clocks to enable insertion of pipelined functions into programmable logic circuitry and increasing the clock frequency of programmable logic circuitry.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

As cryptographic and blockchain applications become increasingly prevalent, integrated circuits are increasingly used in computation of very large combinatorial functions. For example, in a single cycle of such a large function, a signal may pass though on the order of hundred thousand arithmetic logic modules (ALMs). In addition, the computation in such a function may include on the order of a thousand bits. Such large functions may need to have embedded elements such as digital signal processing blocks or M20K memories embedded in them. Currently, large functions are incompatible with embedded elements such as DSP blocks. In addition, reported timing for large systems, especially those containing large combinational circuits, can be overly conservative. Currently, there no effective methods for increasing the timing of large systems.

### BRIEF DESCRIPTION OF THE DRAWINGS

Various aspects of this disclosure may be better understood upon reading the following detailed description and upon reference to the drawings in which:

FIG. 1 illustrates a block diagram of a system that may implement arithmetic operations using a DSP block, in accordance with an embodiment of the present disclosure;

FIG. 2 illustrates an example of the integrated circuit device as a programmable logic device, such as a field-programmable gate array (FPGA), in accordance with an embodiment of the present disclosure;

FIG. 3 is a block diagram of a first design of a function including a logic circuit and a non-pipelined DSP block that is embedded in the logic circuit, in accordance with an embodiment of the present disclosure;

FIG. 4 is a schematic diagram of a second design of the function including multiple signal propagation paths with logic circuits and embedded DSP blocks, in accordance with an embodiment of the present disclosure;

FIG. 5 is a schematic diagram of a third design of the function including multiple logic circuits and multiple embedded DSP blocks in each signal propagation path, in accordance with an embodiment of the present disclosure;

FIG. 6 is a schematic diagram of a fourth design of a function that includes a logic circuit and an embedded pipelined DSP block, in accordance with an embodiment of the present disclosure;

FIG. 7 is an illustration of the dataflow through a function of FIG. 6 as well as a main clock and a faster clock that may be used by the function of FIG. 6, in accordance with an embodiment of the present disclosure;

FIG. 8 is an illustration the dataflow through a function of FIG. 6, the main clock, and the faster clock that only includes the pulses used by the pipelined DSP block, in accordance with an embodiment of the present disclosure;

FIG. 9 is an illustration of a dataflow through the function of FIG. 5, the main clock, and multiple faster clocks, in accordance with an embodiment of the present disclosure;

FIG. 10 is an illustration of the main clock and several phase-shifted instances of the faster clock, in accordance with embodiments of the present disclosure;

FIG. 11 is an illustration of the main clock and the faster clock that includes an early pulse, an average pulse, and a late pulse, in accordance with an embodiment of the present disclosure;

FIG. 12 is a block diagram of a function that samples the output of a logic circuit with three pulses of the faster clock, in accordance with an embodiment of the present disclosure;

FIG. 13 is a block diagram of an iterative function that samples the output of the logic circuit with the three pulses of a faster clock, in accordance with an embodiment of the present disclosure;

FIG. 14 is a block diagram of a function that samples the output of the logic circuit with seven pulses of a faster clock, in accordance with an embodiment of the present disclosure;

FIG. 15 is a diagram of a main clock and of a faster clock that includes seven pulses: five early pulses, an average pulse, and a late pulse, in accordance with an embodiment of the present disclosure;

FIG. 16 is an illustration of the main clock and a faster clock with a relatively high pulse frequency, in accordance with an embodiment of the present disclosure; and

FIG. 17 is an illustration of the main clock and a faster clock where the average pulse, the late pulse, and first early pulse are distributed at a later time range and four other early pulses are distributed at an earlier time range, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “including” and “having” are intended to be inclusive and mean that there may be additional elements other than the listed elements. Additionally, it should be understood that references to “some embodiments,” “embodiments,” “one embodiment,” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

As cryptographic and blockchain applications become ever more prevalent, there is a growing desire for circuitry to perform very large (e.g., computationally complex, involving many bits) recursive calculations that are used in cryptographic functions. To enable hardware designs for efficient computation of cryptographic functions, the circuitry may be extended to include digital signal processing (DSP) block functionality. In addition, the circuitry may include logic circuitry that may be used for implementing custom designs of cryptographic functions.

The logic circuitry associated with cryptographic functions, such as variable delay functions, may be large and complex, and therefore may take relatively long periods of time to produce a stable output. Currently, there is a desire to have pipelined DSP blocks embedded in the logic circuitry. However, the pipelined DSP blocks may not be used effectively when embedded in logic circuitry because the embedded DSP blocks may produce a stable output on a relatively shorter time scale than the logic circuitry and, therefore, may not effectively utilize the clock signal used by a main register of the logic circuitry. The present disclosure describes techniques for incorporating pipelined DSP blocks or other types of embedded functions into logic circuitry with slower clock rate (e.g., than the clock rate of the pipelined function) without clock crossing complexities and at the same time managing the power consumption of the more complex design that results from it. The techniques for incorporating pipelined DSP blocks into logic circuitry may include generating a faster clock or several phase-shifted faster clocks that have a faster clock rate and that may be used as clock input to the embedded pipelined DSP blocks.

An additional application of the generated faster clocks may include using the pulses of the faster clocks to sample the output of a large circuit (e.g., a logic circuit) and to safely “overclock” the circuit. Thus, in addition to presenting techniques for incorporating embedded pipelined functions into a logic circuitry, the present disclosure describes techniques for sampling output of a logic circuit using pulses of generated faster clock and increasing the clock frequency of the circuit to an optimal level. Such techniques may include generating clock pulses that correspond to an estimated clock rate at which the data in the circuit may stabilize and generating clock pulses corresponding to clock rates that may lead and lag the estimated rate. The output of the circuit is sampled by the pulses corresponding to the different rates compared to the reported rate. A histogram of errors at all the sampling points may be used to identify a fastest rate that is supported by the circuit at a particular time. Thus, clock period of the circuit can be stretched or shrunk in real time depending on results of the sampling. This may increase operating maximum frequency of the circuit by 15%-30% and result in throughput improvements in circuits that used in cryptography and block chain applications.

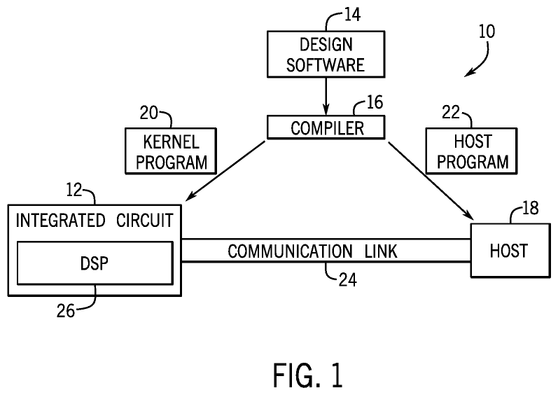

With this in mind, FIG. 1 illustrates a block diagram of a system 10 that may implement arithmetic operations using a DSP block. A designer may desire to implement functionality, such as, but not limited to, computation of cryptographic functions, on an integrated circuit device 12 (such as a field-programmable gate array (FPGA) or an application-specific integrated circuit (ASIC)). In some cases, the designer may specify a high-level program to be implemented, such as an OpenCL program, which may enable the designer to more efficiently and easily provide programming instructions to configure a set of programmable logic cells for the integrated circuit device 12 without specific knowledge of low-level hardware description languages (e.g., Verilog or VHDL). For example, because OpenCL is quite similar to other high-level programming languages, such as C++, designers of programmable logic familiar with such programming languages may have a reduced learning curve than designers that are required to learn unfamiliar low-level hardware description languages to implement new functionalities in the integrated circuit device 12.

The designers may implement their high-level designs using design software 14, such as a version of Intel® Quartus® by INTEL CORPORATION. The design software 14 may use a compiler 16 to convert the high-level program into a lower-level description. The compiler 16 may provide machine-readable instructions representative of the high-level program to a host 18 and the integrated circuit device 12. The host 18 may receive a host program 22 which may be implemented by the kernel programs 20. To implement the host program 22, the host 18 may communicate instructions from the host program 22 to the integrated circuit device 12 via a communications link 24, which may be, for example, direct memory access (DMA) communications or peripheral component interconnect express (PCIe) communications. In some embodiments, the kernel programs 20 and the host 18 may enable configuration of one or more DSP blocks 26 on the integrated circuit device 12. The DSP block 26 may include circuitry to implement, for example, operations to perform matrix-matrix or matrix-vector multiplication for AI or non-AI data processing. The integrated circuit device 12 may include many (e.g., hundreds or thousands) of the DSP blocks 26. Additionally, DSP blocks 26 may be communicatively coupled to another such that data outputted from one DSP block 26 may be provided to other DSP blocks 26.

While the techniques above discussion described to the application of a high-level program, in some embodiments, the designer may use the design software 14 to generate and/or to specify a low-level program, such as the low-level hardware description languages described above. Further, in some embodiments, the system 10 may be implemented without a separate host program 22. Moreover, in some embodiments, the techniques described herein may be implemented in circuitry as a non-programmable circuit design. Thus, embodiments described herein are intended to be illustrative and not limiting.

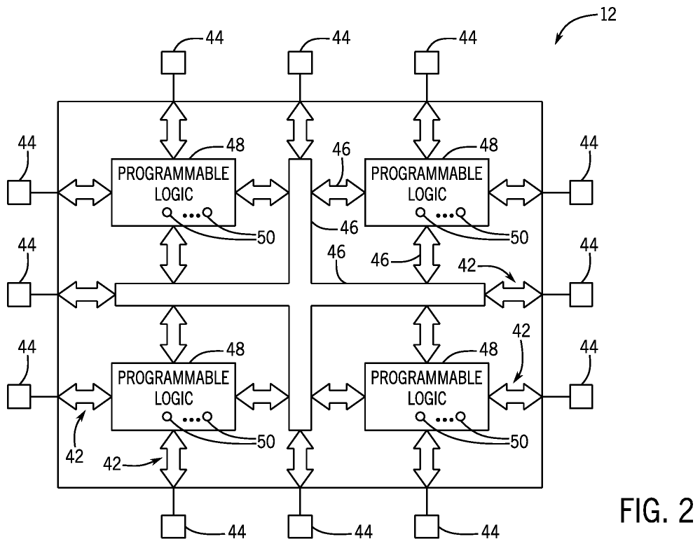

Turning now to a more detailed discussion of the integrated circuit device 12, FIG. 2 illustrates an example of the integrated circuit device 12 as a programmable logic device, such as a field-programmable gate array (FPGA). Further, it should be understood that the integrated circuit device 12 may be any other suitable type of integrated circuit device (e.g., an application-specific integrated circuit and/or application-specific standard product). As shown, the integrated circuit device 12 may have input/output circuitry 42 for driving signals off device and for receiving signals from other devices via input/output pins 44. Interconnection resources 46, such as global and local vertical and horizontal conductive lines and buses, may be used to route signals on integrated circuit device 12. Additionally, interconnection resources 46 may include fixed interconnects (conductive lines) and programmable interconnects (e.g., programmable connections between respective fixed interconnects). Programmable logic 48 may include combinational and sequential logic circuitry. For example, programmable logic 48 may include look-up tables, registers, and multiplexers. In various embodiments, the programmable logic 48 may be configured to perform a custom logic function. The programmable interconnects associated with interconnection resources may be considered to be a part of the programmable logic 48.

Programmable logic devices, such as integrated circuit device 12, may contain programmable elements 50 within the programmable logic 48. For example, as discussed above, a designer (e.g., a customer) may program (e.g., configure) the programmable logic 48 to perform one or more desired functions. By way of example, some programmable logic devices may be programmed by configuring their programmable elements 50 using mask programming arrangements, which is performed during semiconductor manufacturing. Other programmable logic devices are configured after semiconductor fabrication operations have been completed, such as by using electrical programming or laser programming to program their programmable elements 50. In general, programmable elements 50 may be based on any suitable programmable technology, such as fuses, antifuses, electrically programmable read-only-memory technology, random-access memory cells, mask-programmed elements, and so forth.

Many programmable logic devices are electrically programmed. With electrical programming arrangements, the programmable elements 50 may be formed from one or more memory cells. For example, during programming, configuration data is loaded into the memory cells using pins 44 and input/output circuitry 42. In one embodiment, the memory cells may be implemented as random-access-memory (RAM) cells. The use of memory cells based on RAM technology is described herein is intended to be only one example. Further, because these RAM cells are loaded with configuration data during programming, they are sometimes referred to as configuration RAM cells (CRAM). These memory cells may each provide a corresponding static control output signal that controls the state of an associated logic component in programmable logic 48. For instance, in some embodiments, the output signals may be applied to the gates of metal-oxide-semiconductor (MOS) transistors within the programmable logic 48.

### Incorporating Embedded Functions into Logic Circuitry

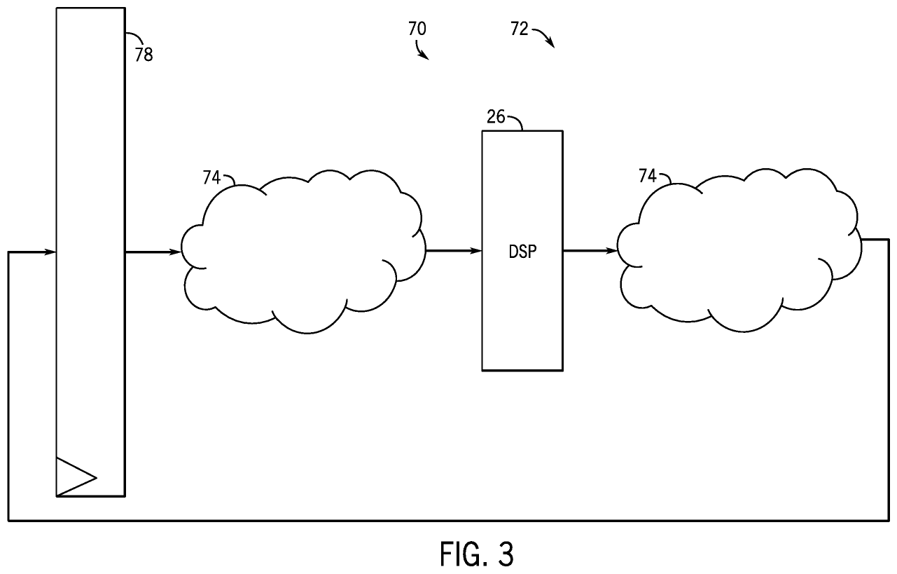

Keeping the foregoing in mind, the DSP block 26 along with programmable logic 48 discussed herein may be user to perform many different operations associated with the cryptographic applications, such as computation of exponential multiplication products, execution of variable delay functions (VDFs), etc. VDFs and other functions used in cryptographic application may include complex computations that may be implemented as logic circuits that may include programmable logic 48. In addition, DSP blocks or other types of functions may be embedded into the logic circuitry. Several possible designs of cryptographic functions such as VDFs are shown in FIGS. 3-6.

With the foregoing in mind, FIG. 3 is a block diagram of a first design 70 of a function 72 (e.g., a cryptographic function) including a logic circuit 74 and DSP block 26 (e.g., combinatorial DSP block) that is embedded in the logic circuit 74. In an embodiment, the logic circuit 74 may include programmable logic that may enable the logic circuit 74 to be customized to perform certain operations. In addition, the logic circuit 74 may include a large number of elements such as lookup tables (LUTs) and/or arithmetic logic modules (ALMs) though which a signal (e.g., electrical signal) may pass during a computation. The execution of a cycle of the function 72 includes an electrical signal propagating through the first portion of the logic circuit 74, though the embedded DSP block 26, and then though second portion of the logic circuit 74, before the output of the function 72 is latched by a main register 78. It may take a longer time for the signal to propagate though the logic circuit 74 than thorough the embedded DSP block 26. Accordingly, the output of the DSP block 26 may be ready (e.g., the output signal of the DSP block 26 may be steady) faster than the output of the logic circuit 74.

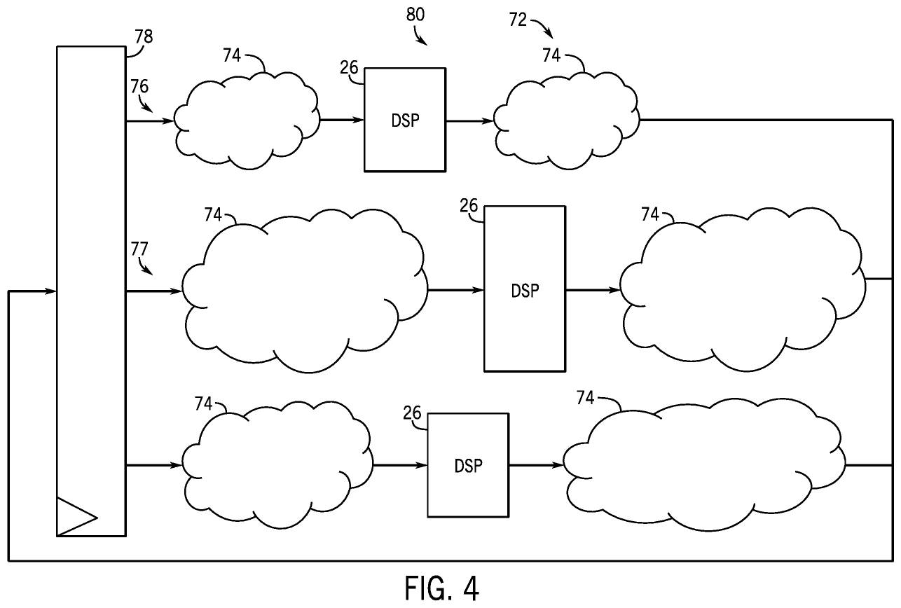

The first design 70 is a typical, yet very simple, design of the function 72 (e.g., variable delay function), which is used in cryptographic applications. A more realistic example of a design of the function 72 is shown in FIG. 4. FIG. 4 is a schematic diagram of a second design 80 of the function 72 including multiple signal propagation paths with logic circuits 74 and embedded DSP blocks 26 (e.g., non-pipelined DSP blocks). As shown, the function 72 may include multiple paths (e.g., signal propagation paths), each path associated with an input from the main register 78 and each path including multiple logic circuits 74 and embedded DSP blocks 26, through which a signal (e.g., input signal) may travel.

Depending on their design (e.g., customization, configuration, number of components, etc.), different logic circuits 74 may have different propagation times of signals traveling through them. Thus, signal may reach different DSP blocks 26 shown in FIG. 4 at different times and computation associated with the different DSP blocks 26 may begin at different times. For example, the signal may propagate quicker through the logic circuit 74 in the top path 76 than the signal propagating through the logic circuit 74 in the middle path 77. Thus, computation associated with DSP block 26 in the top path 76 will begin before the computation associated with the DSP block 26 in the middle path 77.

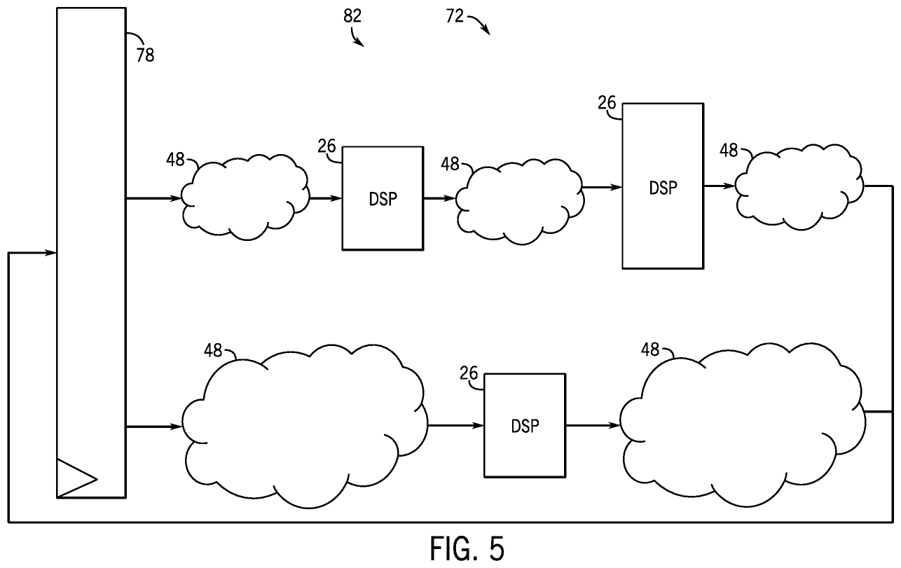

In an embodiment, the functions (e.g., function 72) used in cryptographic applications may have multiple logic circuits 74 and embedded DSP blocks 26 in a single path of a signal. FIG. 5 is a schematic diagram of a third design 82 of the function 72 including multiple logic circuits 74 and multiple embedded DSP blocks 26 in each signal propagation path. Thus the third design 82 has an added complexity (e.g., as compared to the first design 70 and the second design 80) as several different embedded DSP blocks 26 and logic circuits 74 may be executed sequentially in a single path. In addition, it should be understood that embedded DSP blocks are presented herein as an example of a type of element that may be embedded in a signal path and/or in a logic circuit 74. Accordingly, the designs (e.g., first design 70, second design 80, third design 82, fourth design 84) of the function 72 presented herein may also have other types of embedded elements such as embedded memory blocks (e.g., M2OK memories found in FPGA devices by Intel Corporation).

The embedded DSP blocks 26 (or other embedded elements such as M2OK memories) may have either combinatorial or pipelined structure. While a combinatorial DSP block may wait for its output to be ready before receiving the next input, a pipelined DSP block may include several stages (e.g., register stages) that are associated with pipeline registers that allow the pipelined DSP block to receive a next input once the output of the first stage is ready (e.g., has been latched by the first pipeline register). Thus, the pipelined DSP blocks may process several inputs at a time and may have higher throughput. Just like the combinational DSP blocks, pipelined DSP blocks may be embedded in the logic circuits 74 of the function 72 (e.g., cryptographic function).

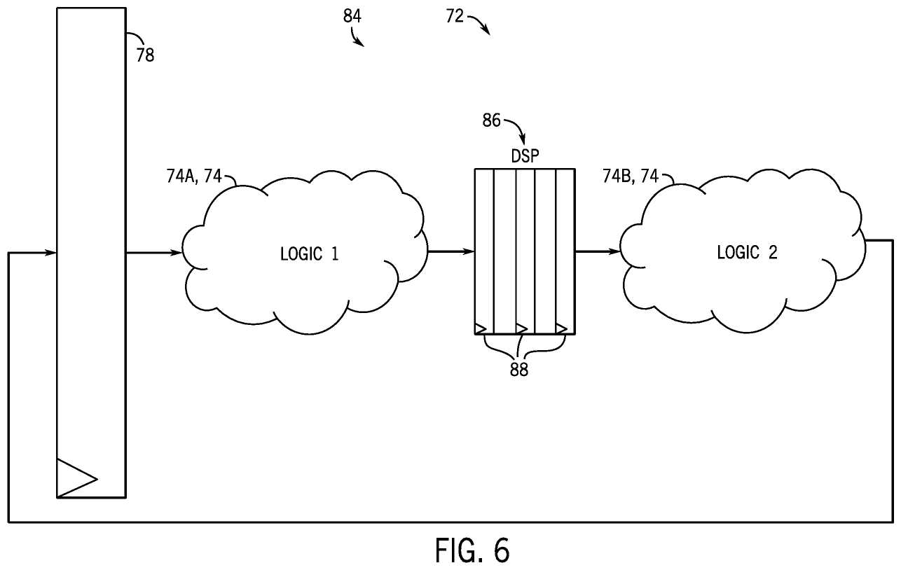

FIG. 6 is a schematic diagram of a fourth design 84 of a function 72 that includes a logic circuit 74 and an embedded pipelined DSP block 86. In particular, the function 72 includes a first logic circuit 74A (e.g., logic 1), a second logic circuit 74B (e.g., logic 2), and the pipelined DSP block 86 that has three pipeline stages. Each pipeline stage may be associated with a pipeline register 88 receiving a clock input.

Currently, pipelined DSP blocks 86 may not be used effectively when embedded logic circuits 74 that are computationally complex, because clock rate associated with the main register 78 of the function 72 may be significantly slower than the clock rate associated with the pipelined registers 88 of the pipelined DSP block 86. For example, the function 72 may represent a relatively large modular multiplier (1024 bits), that may run (e.g., finish computing) on the order of 20 nanoseconds (ns) or 50 Megahertz (MHz). However, the pipelined DSP 86 may run much faster, such as on an order of 500 MHz to 1 Gigahertz (GHz) or 2 ns to 1 ns.

If the function 72 only includes a single embedded pipelined DSP block 86 that has only a single register stage, then the output of the first stage of the pipelined DSP block 86 may be latched on the negative clock edge of the clock (e.g., main clock) associated with the main register 78 (e.g., the clock associated with the whole function 72). However, this may only work if the embedded element has a single pipeline stage and finishes processing exactly in the middle clock cycle of the main clock. Thus, latching the output of the embedded pipelined DSP block 86 on the negative clock edge of the main clock may not work for function designs shown in FIG. 3 and FIG. 4.

To be enable effective use of pipelined DSP blocks 86 embedded into large logic circuits 74, a second faster clock may be generated and used to run the pipeline registers 88 of the pipelined DSP blocks 86. The faster clock may allow to implement the fourth design 84 of the function 72 that is close to performance to a first design 70 of the function 72. In other words, the function 72 that may include an embedded pipelined DSP block 86 without a significant loss in performance (e.g., computational time increases, etc.) and with minimum additional complexity.

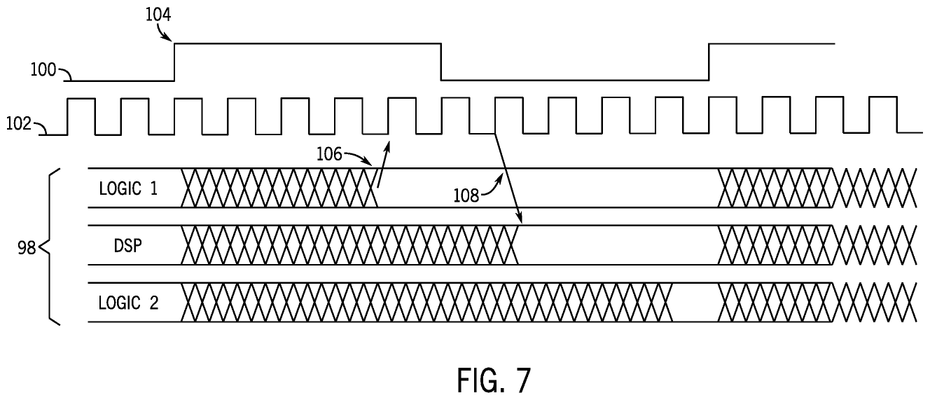

FIG. 7 is an illustration of the dataflow 98 through a function 72 of FIG. 6 as well as the main clock 100 and the faster clock 102 that may be used by the function 72. In particular, FIG. 7 shows how fast the dataflow 98 of each circuit element (e.g., pipelined DSP block 86 and logic circuit 74) of function 72 stabilizes over a single clock period of the main clock 100. The dataflow 98 indicates that the output of the first logic circuit 74A becomes stable after a relatively short amount of time (e.g., about four cycles of the faster clock), the processing of the signal by the pipelined DSP block 86 takes an additional three clock cycles of the faster clock 102. The second logic circuit 74B becomes stable after almost 10 clocks cycles of the faster clock (e.g., one cycle of the main clock) and its output latched by the main register 78 on the rising edge 104 of the main clock 100. Arrow 106 indicates the rising edge of the faster clock 102 that may latch the output of first logic circuit 74A into the pipelined DSP block 86 and arrow 108 indicates the rising edge of the faster clock that may latch the final output of the pipelined DSP block 86. This should work as long as the long clock cycle is greater than the time through the DSP and the two logic clouds.

As discussed, the main clock 100 may be used as the clock input to the main register 78 while the faster clock 102 may be used as the clock input into the pipeline registers 88 of the pipelined DSP block 86. Accordingly, the period of the main clock 100 may be the time duration associated with a cycle of the function 72 while the period of the faster clock 102 may be the time duration associated with a pipeline stage of the pipelined DSP block 86. The main clock 100 and the faster clock 102 may be aligned and locked to one another. For example, the main clock 100 and the faster clock 102 may be synchronized such that the rising edge 104 of the main clock 100 occurs at the same time as the rising edge of the faster clock 102 and each cycle of the main clock 100 corresponds to a certain number of cycles of the faster clock 102. As discussed, the faster clock 102 shown may run several times faster than the main clock 100. For example, the faster clock 102 shown FIG. 7 runs ten times faster than the main clock 100.

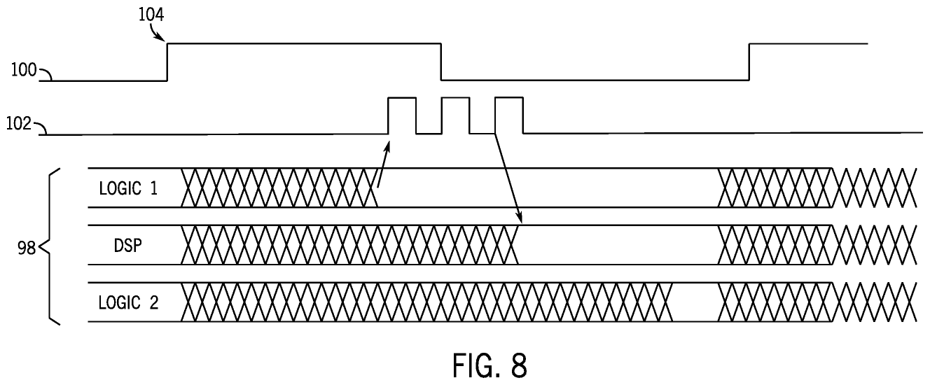

In the illustrated embodiment, only three clock periods of the fast clock 102 are processing stable data. That is, only three clock periods of the faster clock 102 may latch stable output of the register stages of the pipelined DSP block 86. Accordingly, it may be desirable to have the faster clock 102 only run when it is useful for input into the pipelined DSP block 86. This scenario is illustrated in FIG. 8. FIG. 8 is an illustration the dataflow 98 through a function 72 of FIG. 6, the main clock 100, and the faster clock 102, which only includes the pulses used by the pipelined DSP block 86. For example, the three clock cycles (e.g., three pulses) of the faster clock 102 may be generated once the output of the first logic circuit 74A is stable.

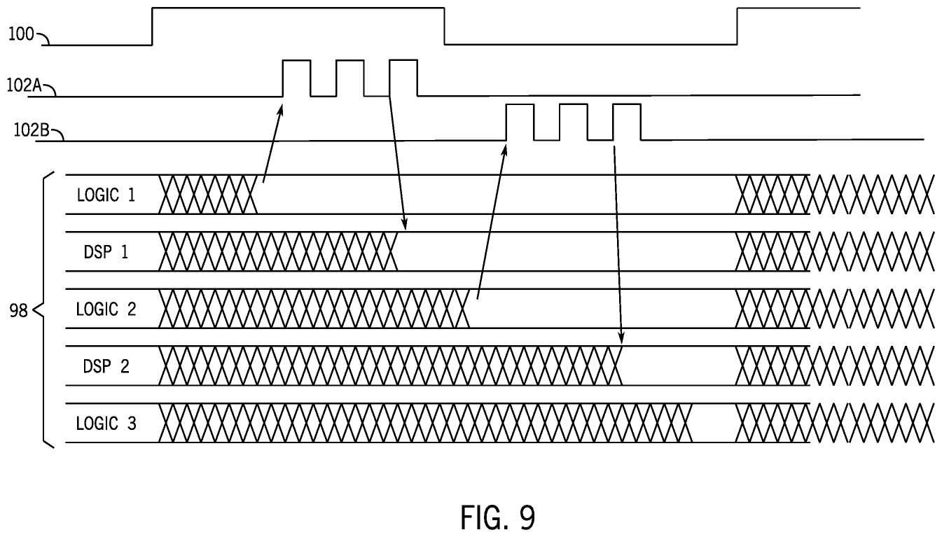

In a case where several pipelined DSP blocks 86 are embedded in a path of the function 72, as shown in FIG. 5, or were the pipelined DSP blocks 86 are located at different time delays (e.g., from a time when the data was latched), as shown in FIG. 4 and FIG. 5, multiple generated faster clocks 102 may be used to provide input clock signals into the pipelined DSP blocks 86 as shown in FIG. 9. FIG. 9 is an illustration of a dataflow 98 through the function 72 of FIG. 5, the main clock 100, and multiple faster clocks 102. In this scenario, the first faster clock 102A may be used as the clock input into the first pipelined DSP block 86 and the second faster clock 102B may be used as the clock input into the second pipelined DSP block 86. In an embodiment, the second faster clock 102B may be a different phase of the first faster clock 102A. It should be appreciated that it may be possible to use just a single faster clock 102 as the clock input into both the first pipelined DSP block 86 and the second pipelined DSP block 86. However, in this case the faster clock 102 may latch data that is not fully stable.

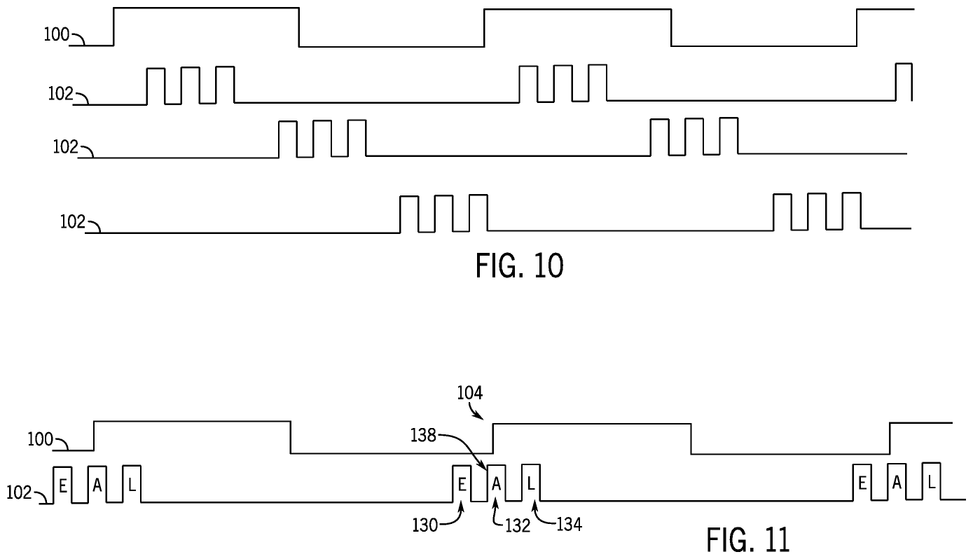

In an embodiment, it may be desirable to only apply the faster clock 102 to the embedded pipelined DSP blocks 86 when the outputs of the logic circuit 74 preceding pipelined DSP blocks 86 are stable (e.g., to reduce power consumption associated with the execution of the function 72) . In this case, multiple instances (e.g., phases) of the faster clock 102 may be generated and applied to the pipelined DSP blocks 86, as shown in FIG. 10. FIG. 10 is an illustration of the main clock 100 and of several phase-shifted instances of the faster clock 102. Specifically, the generated faster clocks 102 may repeat with the same period as the main clock 100.

### Overclocking of Large Combinatorial Circuits

In addition to enabling effective incorporation of embedded functions into combinatorial logic circuits 74, a faster clock (e.g., a clock that is faster than the clock associated with the main register 78) may be used to sample an output of a large logic circuit 74 and identify an optimal clock rate for the large logic circuit 74 in real time. In particular, pulses of the faster clock 102 may sample the output of the logic circuit 74 by enabling several different output registers. For example, the signal of the logic circuit 74 that may be sampled by three different registers at three different times: early (E), average (A), and late (L). FIG. 11 shows a faster clock 102 that may be used to sample the output (e.g., signal) of a logic circuit 74 using the three pulses of the faster clock 102. It should be appreciated that the logic circuit 74 discussed henceforth may not necessarily have embedded DSP blocks 26 or other embedded functions. However, logic circuit 74 may still include programmable logic 48 as well as a large number of LUTs and/or ALMs. In addition, it should be understood that average time refers to a time that occurs after the early time and before the late time, rather than being a statistical average of the early time and late time. Accordingly, the average (e.g., intermediate) pulse may occur between the early pulse and the late pulse without necessarily being equidistant in time to either of them.

FIG. 11 is an illustration of a main clock 100 of a function (e.g., circuit) and of a corresponding faster clock 102 that includes an early pulse 130, an average pulse 132, and a late pulse 134. As shown, rising edge 138 of the average pulse 132 occurs at the same time as the rising edge 104 of the main clock 100. Thus, the average pulse 132 may occur at the time when the signal is expected to correct (e.g., stable). The time at which the average pulse 132 may sample the correct signal may vary with a number of different parameters, such as temperature. The time at which the pulses are generated may be adjusted by the clock pulse generation circuit. In an embodiment, the time when the output of a logic circuit 74 is expected to be correct may be estimated by software that is used to simulate, program, or configure the logic circuit 74. The late pulse 134 may occur when the output signal is most likely to be stable and is substantially guaranteed to be correct. The late time sampling may occur after the rising edge of the main clock 100 and/or after the output of the logic circuit 74 has been latched by the main register 78. The values sampled by the pulses may be compared to determine whether the signal latched by the average pulse 132 is stable and whether the timing of the pulses may need to be adjusted. For example, if the values sampled by the average pulse 132 and the late pulse 134 are not the same, the average pule may have occurred too soon and the clock speed (e.g., clock rate, frequency) of the faster clock 102 may be adjusted such that the sampling by the average pulse 132 may be delayed (e.g., by decreasing the frequency of the fast clock 102 or shifting the late pulse 134 to a later time).

Similarly, the output value latched at the rising edge of the early pulse 130 may be compared with the value latched at the rising edge 138 of the average pulse 132. In this case, the value that is sampled by the early pulse 130 is expected to be different from the value that is sampled by the average pulse 132. If the values produced by the early sampling and the average sampling are consistently the same, the average pulse 132 samples the output too late. In this case, the clock rate of faster clock 102 may be adjusted to cause the average pulse 132 to arrive earlier. For example, the clock rate of the faster clock 102 may be increased (or the faster clock 102 may be phase-shifted) so that average pulse 132 may occur at the time of the early pulse 130. A threshold may be employed to determine whether to shift the average pulse 132 to an earlier time in the next clock cycle of the main clock. For example, if the match rate between early and average sampling exceeds a threshold of 50%, the rate of the faster clock 102 may adjusted to cause the average sampling to occur earlier.

The sampling described above may be used to increase the overall clock rate and, therefore, the performance of the computation associated with a logic circuit 74. For example, the average circuit (e.g., logic circuit 74 whose output is latched by the average pulse 132) is expected to be around 15% faster than the late circuit (e.g., logic circuit 74 whose output is latched by the late pulse 134). Thus, latching the output of the circuit with an average pulse 132 may allow to increase the computational performance by 15%. In addition, the sampling described herein may provide a safe (e.g., without occurrence of unmitigated errors) way to increase the overall clock frequency of the logic circuit 74, as the comparison of the output signals latched at different times allows to ensure that the signal is latched only when it is stable. Thus, faster computational time can be achieved for the logic circuit 74 without sacrificing the accuracy of the output.

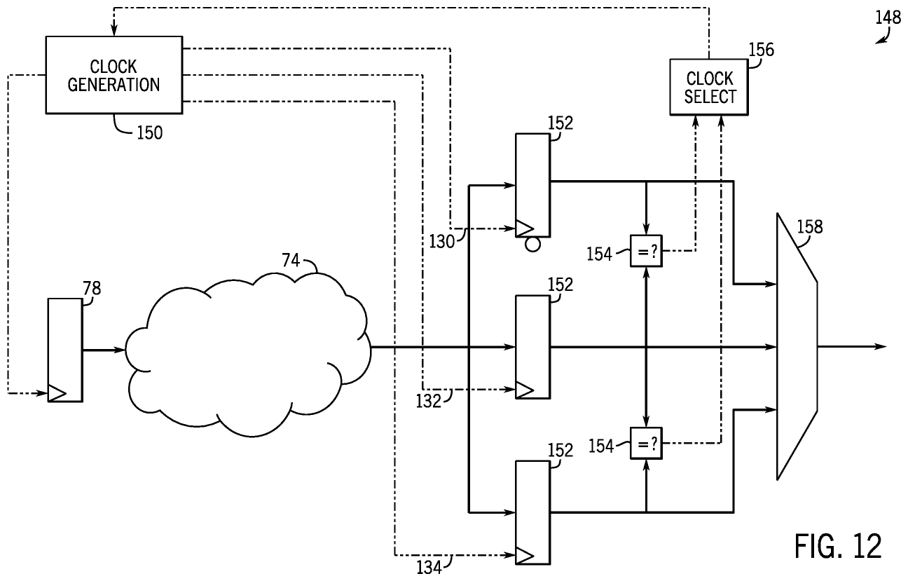

FIG. 12 is a block diagram of a function 148 that samples the output of a logic circuit 74 with three pulses of the faster clock 102. A clock generator circuit 150 may output three time-shifted pulses (e.g., early pulse 130, average pulse 132, late pulse 134) that are used to sample the output of a logic circuit 74 at three different times: early, average, and late. The signal of the logic circuit 74 may be latched by output registers 152. The outputs may be routed to all of the output registers 152 in parallel, but the output registers 152 are latched by different clock pulses at different times. Thus, there may be three outputs of the logic circuit 74.

The comparators 154 may compare the outputs sampled by the early pulse 130 and the average pulse 132 as well as the outputs sampled by the average pulse 132 and the late pulse 134, and, based on the comparisons, feedback may be sent to the clock generator circuit 150 indicating whether the clock rate (e.g., frequency) of the faster clock 102 needs to be sped up or slowed down. In particular, clock selection circuitry 156 may take as an input the output from the comparators 154 and provide, as an output, a signal indicating whether the sampling occurs too early, too late, or at the right time. In an embodiment, a histogram of errors (e.g., errors resulting from an unstable signal being latched by an output register 152) may be constructed for all sampling points and used to determine whether the clock rate of the faster clock 102 may need to be adjusted. For example, if the histogram of errors has a peak (e.g., large number of filled bins) on or near an average sampling point (e.g., sampling point corresponding to the average pulse 132), the rate of the faster clock 102 may be adjusted to ensure that the average pulse 132 occurs at a later time in the next clock cycle. Accordingly, the feedback sent to the clock generator circuit 150 may be used to adjust the clock rate of the sampling pulses in real time (e.g., based on results of the current sampling).

In an embodiment, the final output of the logic circuit 74 (e.g., the output of the function 148) may be selected via a multiplexer 158 that may receive candidate output values from the output registers 152 and may select the final output value based on input from the comparators 154. In another embodiment, the output of the logic circuit 74 may be wired to the value sampled by the average pulse 132, without the use of a multiplexer 158.

The logic circuit 74 may be combinational. Alternatively, the logic circuit 74 may include embedded functions, such DSP blocks 26. As discussed with reference to FIGS. 3-10, the embedded functions may be pipelined operating on a faster clock 102 that is only active for a subset of the period of the main clock 100.

In an embodiment, the function 148 may be iterative as shown in FIG. 13. FIG. 13 is a block diagram of an iterative function 160 that samples the output of a logic circuit 74 with the three pulses of a faster clock 102. In this embodiment, the final output of the logic circuit 74 would be latched by the main register 78 and provided, via a multiplexer 157, as an input to the logic circuit 74 in the next iteration. In this configuration, the clock selection circuit 156 may delay the start of the next latching of the input in case the value sampling by the pulses of a faster clock 102 produces an error.

If the logic circuit 74 is large (e.g., complex, including many bits or circuit elements), there may be a large number of possible sampling positions in the clock period of the main clock 100 (e.g., due to the period of the main clock 100 being relatively long). This may ensure that the clock period of the fast clock 102 may be easily decreased and increased and that the generation and adjustment of the clock pulses may be easily implemented. For example, a time of signal propagation through the logic circuit 74 may be relatively long (e.g., on the order of 100 ns period of the main clock). Thus, the frequency of the main clock 100 may be 10 MHz while the frequency of the fast clock 102 may be 500 MHz. Thus, there may be 50 possible sampling positions (e.g., pulses of the fast clock 102) in a single clock period of the main clock 100.

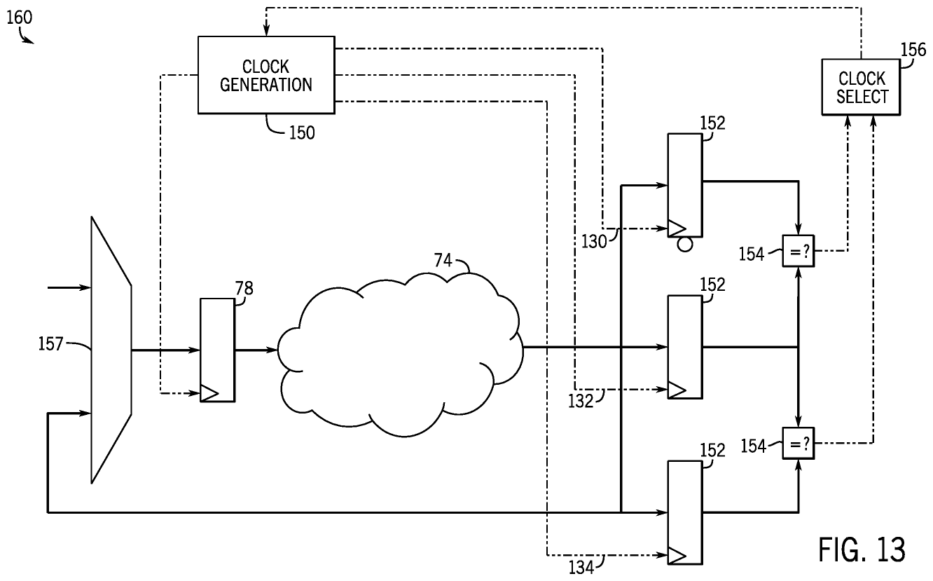

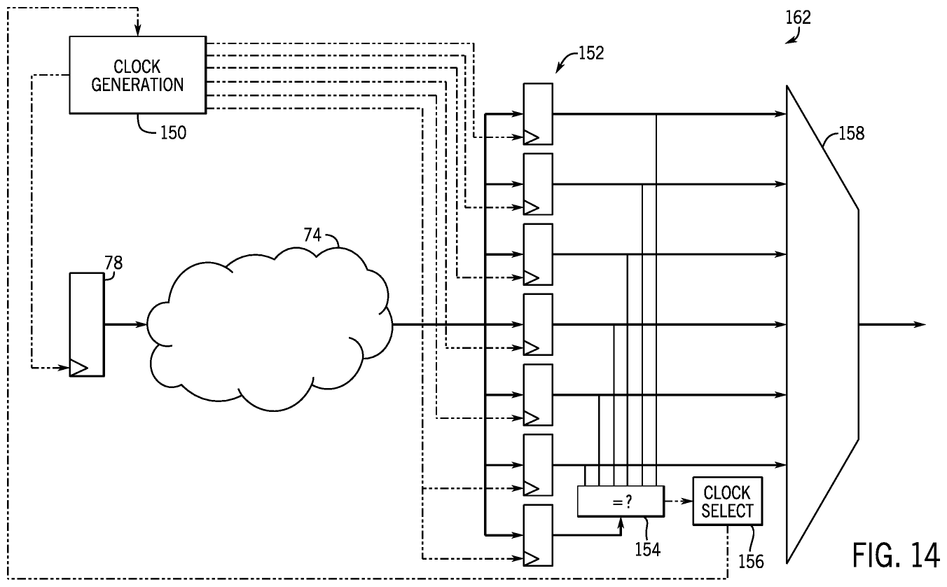

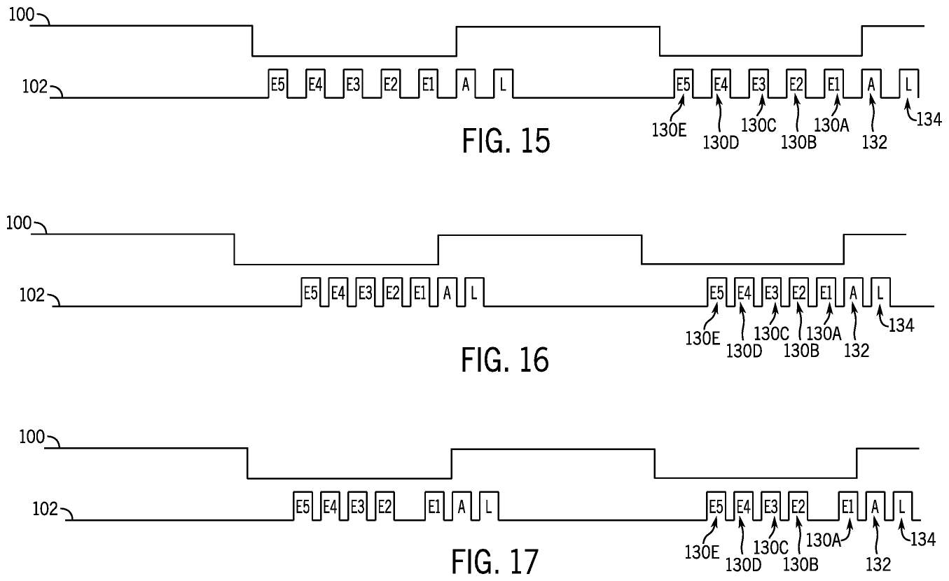

It should be appreciated that any number of sampling pulses of the fast clock 102 may be used to sample the signal of the logic circuit 74. Having more sampling points may enable to sample more outputs at additional times and to possibly find the optimal sampling rate that corresponds to the optimal performance of the circuit sooner. For example, the faster clock 74 may include seven sampling pulses. FIG. 14 is a block diagram of a function 162 that samples the output of a logic circuit 74 with seven pulses of a faster clock 102. In this configuration, there are seven output registers 152 that may latch signal from the logic circuit 74 at seven different sampling times. Aside from having a larger number of output registers 152, the function 162 presented in FIG. 14 may operate in a similar fashion to the iterative function 160 presented in FIG. 13. An example of the sampling pulses of the faster clock 102 that may be used by the function 162 is shown in FIG. 15. FIG. 15 is an illustration of a main clock 100 and of a faster clock 102, which includes seven pulses: five early pulses 130A-130E, an average pulse 132, and a late pulse 134.

It may be inefficient to compare many samples both in terms of amount of logic resources used and in terms of routing required to put the sampled data together. Accordingly, in an embodiment, if there are many samples, only the paths with relatively long propagation delays may be compared. This may mean that only the sampling points that occur later may be processed (e.g., compared). Then, if it is determined that the sampling points that occur later consistently sample stable (e.g., correct) output, earlier sampling points may be processed in subsequent iterations.

In an embodiment, sampling points that are expected to correspond to a target performance increase (e.g., 15% increase in the clock rate from the clock rate that is guaranteed to be correct) may be evaluated (e.g., compared) first. If the target performance increase may be effectively reached, sampling points corresponding to higher performance increases (e.g., 20% increase) may be evaluated in the next iterations. In an embodiment, once sampling point has been identified for a target performance rate (e.g., with multiple sampling points this is may be, for example, between the third early pulse 130C and second early pulse 130B), a sampling with a higher pulse frequency may be used to further improve the sampling point. FIG. 16 is an illustration of a main clock 100 and of a faster clock 102 with a higher pulse frequency.

It should be appreciated that the clock rate (e.g., frequency) of the faster clock 102 may not be continuous. In particular, it may be desirable to keep the late pulse 134 at a time when the output is guaranteed to be stable and the average pulse 132 at a time when the output is expected to be stable; yet the early sampling time points (e.g., early pulses 130A-130E) may be shifted to an early time range that is earlier than when the output is expected. In this case, clock pulses that would occur between the expected time range and the early time range may not be generated, as shown in FIG. 17. FIG. 17 is an illustration of a main clock 100 and of a faster clock 102 where the average pulse 132, late pulse 134, and the first early pulse 130A are distributed in a later time range and the four early pulses 130B-130C are distributed in an earlier time range.

In an embodiment, a software (e.g., FPGA software) may automatically insert the clock generators 150, multiplexers (e.g., multiplexer 158, multiplexer 157), comparators 154, and concurrently determine the placement and routing of this logic elements. In addition, the software may set the frequency of the main clock 100 and the faster clock 102 and may adjust the frequency or the pulse timing (e.g., pulse pattern, time of pulse arrival) of the faster clock 102.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

EXAMPLE EMBODIMENT 1. An integrated circuit comprising: programmable logic circuitry; a register configurable to receive an output of the programmable logic circuitry and configurable to receive a first clock signal; and embedded function circuitry comprising one or more pipeline registers, wherein the embedded function circuitry is configurable to receive a second clock signal, wherein the second clock signal has a higher frequency than the first clock signal.

EXAMPLE EMBODIMENT 2. The integrated circuit of example embodiment 1, wherein the second clock signal is aligned and locked to the first clock signal.

EXAMPLE EMBODIMENT 3. The integrated circuit of example embodiment 1, wherein the programmable logic circuitry comprises field programmable gate array (FPGA) circuitry.

EXAMPLE EMBODIMENT 4. The integrated circuit of example embodiment 1, wherein the embedded function circuitry comprises a digital signal processing (DSP) block, an embedded memory, or both.

EXAMPLE EMBODIMENT 5. The integrated circuit of example embodiment 1, wherein the second clock signal comprises clock pulses configurable to latch a signal of the embedded function circuitry to the one or more pipelined registers during each clock cycle of the first clock signal.

EXAMPLE EMBODIMENT 6. The integrated circuit of example embodiment 5, wherein the clock pulses of the second clock signal repeat with each clock cycle of the first clock signal.

EXAMPLE EMBODIMENT 7. The integrated circuit of example embodiment 1, comprising second embedded function circuitry, wherein the second embedded function circuitry comprises one or more pipeline registers and is configurable to receive a third clock signal, wherein the third clock signal comprises a phase-shifted version of the second clock signal.

EXAMPLE EMBODIMENT 8. An integrated circuit comprising: programmable logic circuitry; clock generator circuitry configurable to generate a first clock signal and a second clock signal, wherein a frequency of the first clock signal is lower than the frequency of the second clock signal; a register configurable to provide input to the programmable logic circuitry and configurable to receive the first clock signal; a first output register configurable to receive an early pulse of the second clock signal; a second output register configurable to receive an intermediate pulse of the second clock signal; and a third output register configurable to receive a late pulse of the second clock signal.

EXAMPLE EMBODIMENT 9. The integrated circuit of example embodiment 8, wherein the early pulse is configurable to latch an early signal of the programmable logic circuitry at an early time point.

EXAMPLE EMBODIMENT 10. The integrated circuit of example embodiment 19, wherein the intermediate pulse is configurable to latch an intermediate signal of the programmable logic circuitry at an intermediate time point, wherein the intermediate time point occurs later than the early time point.

EXAMPLE EMBODIMENT 11. The integrated circuit of example embodiment 10, wherein the late pulse is configurable to latch a late signal of the programmable logic circuitry at a late time point, wherein the late time point occurs later than the intermediate time point.

EXAMPLE EMBODIMENT 12. The integrated circuit of example embodiment 11, wherein the clock generator circuitry is configurable to cause the intermediate pulse to occur later in response to the intermediate signal not being equal to the late signal.

EXAMPLE EMBODIMENT 13. The integrated circuit of example embodiment 11, wherein the clock generator circuitry is configurable to cause the intermediate pulse to occur earlier in response to the early signal and the intermediate signal being equal.

EXAMPLE EMBODIMENT 14. The integrated circuit of example embodiment 11, wherein the clock generator circuitry is configurable to increase the frequency of the second clock in response to the early signal and the intermediate signal being equal.

EXAMPLE EMBODIMENT 15. The integrated circuit of example embodiment 8, wherein the frequency of the second clock signal is discontinuous.

EXAMPLE EMBODIMENT 16. The integrated circuit of example embodiment 8, wherein a rising edge of the first clock signal and a rising edge of the intermediate pulse occur simultaneously.

EXAMPLE EMBODIMENT 17. The integrated circuit of example embodiment 8, comprising a multiplexer configurable to receive an input from the first output register, the second output register, and the third output register and to select an output of the integrated circuit to ensure functional correctness by comparing signal stability.

EXAMPLE EMBODIMENT 18. The integrated circuit of example embodiment 17, wherein the frequency of the second clock is determined by a software application and routing of the clock generator circuitry, the multiplexer, one or more comparator, or any combination thereof is determined by the software application.

EXAMPLE EMBODIMENT 19. A method comprising: receiving a first clock signal via a main register, wherein the main register is configurable to receive an output of programmable logic circuitry that comprises embedded function circuitry; receiving a first pulse of a second clock signal via a first pipeline register of the embedded function circuitry and latching the output of the embedded function circuitry via the first pipeline register at the first pulse, wherein the embedded function circuitry comprises a DSP block, an embedded memory, or both; and receiving a second pulse of the second clock signal via a second pipeline register of the embedded function circuitry and latching the output of the embedded function circuitry via the second pipeline register at the second pulse, wherein the second pulse occurs later than the first pulse.

EXAMPLE EMBODIMENT 20. The method of example embodiment 19, wherein the first pulse and the second pulse of the second clock signal occur during a portion of a clock cycle of the first clock signal.

What is claimed is:

1. An integrated circuit comprising:
programmable logic circuitry;
a register configurable to receive an output of the programmable logic circuitry and configurable to receive a first clock signal; and
embedded function circuitry comprising one or more pipeline registers, wherein the embedded function circuitry is configurable to receive a second clock signal, wherein the second clock signal has a higher frequency than the first clock signal.

2. The integrated circuit of claim 1, wherein the second clock signal is aligned and locked to the first clock signal.

3. The integrated circuit of claim 1, wherein the programmable logic circuitry comprises field programmable gate array (FPGA) circuitry.

4. The integrated circuit of claim 1, wherein the embedded function circuitry comprises a digital signal processing (DSP) block, an embedded memory, or both.

5. The integrated circuit of claim 1, wherein the second clock signal comprises clock pulses configurable to latch a signal of the embedded function circuitry to the one or more pipelined registers during each clock cycle of the first clock signal.

6. The integrated circuit of claim 5, wherein the clock pulses of the second clock signal repeat with each clock cycle of the first clock signal.

7. The integrated circuit of claim 1, comprising second embedded function circuitry, wherein the second embedded function circuitry comprises one or more pipeline registers and is configurable to receive a third clock signal, wherein the third clock signal comprises a phase-shifted version of the second clock signal.

8. An integrated circuit comprising:
programmable logic circuitry;
clock generator circuitry configurable to generate a first clock signal and a second clock signal, wherein a frequency of the first clock signal is lower than the frequency of the second clock signal;
a register configurable to provide input to the programmable logic circuitry and configurable to receive the first clock signal;
a first output register configurable to receive an early pulse of the second clock signal;
a second output register configurable to receive an intermediate pulse of the second clock signal; and
a third output register configurable to receive a late pulse of the second clock signal.

9. The integrated circuit of claim 8, wherein the early pulse is configurable to latch an early signal of the programmable logic circuitry at an early time point.

10. The integrated circuit of claim 9, wherein the intermediate pulse is configurable to latch an intermediate signal of the programmable logic circuitry at an intermediate time point, wherein the intermediate time point occurs later than the early time point.

11. The integrated circuit of claim 10, wherein the late pulse is configurable to latch a late signal of the programmable logic circuitry at a late time point, wherein the late time point occurs later than the intermediate time point.

12. The integrated circuit of claim 11, wherein the clock generator circuitry is configurable to cause the intermediate pulse to occur later in response to the intermediate signal not being equal to the late signal.

13. The integrated circuit of claim 11, wherein the clock generator circuitry is configurable to cause the intermediate pulse to occur earlier in response to the early signal and the intermediate signal being equal.

14. The integrated circuit of claim 11, wherein the clock generator circuitry is configurable to increase the frequency of the second clock in response to the early signal and the intermediate signal being equal.

15. The integrated circuit of claim 8, wherein the frequency of the second clock signal is discontinuous.

16. The integrated circuit of claim 8, wherein a rising edge of the first clock signal and a rising edge of the intermediate pulse occur simultaneously.

17. The integrated circuit of claim 8, comprising a multiplexer configurable to receive an input from the first output register, the second output register, and the third output register and to select an output of the integrated circuit to ensure functional correctness by comparing signal stability.

18. The integrated circuit of claim 17, wherein the frequency of the second clock is determined by a software application and physical placement and routing of the clock generator circuitry, the multiplexer, one or more comparator, or any combination thereof is determined by the software application.

19. A method comprising:
receiving a first clock signal via a main register, wherein the main register is configurable to receive an output of programmable logic circuitry that comprises embedded function circuitry;
receiving a first pulse of a second clock signal via a first pipeline register of the embedded function circuitry and latching the output of the embedded function circuitry via the first pipeline register at the first pulse, wherein the embedded function circuitry comprises a DSP block, an embedded memory, or both; and
receiving a second pulse of the second clock signal via a second pipeline register of the embedded function circuitry and latching the output of the embedded function circuitry via the second pipeline register at the second pulse, wherein the second pulse occurs later than the first pulse.

20. The method of claim 19, wherein the first pulse and the second pulse of the second clock signal occur during a portion of a clock cycle of the first clock signal.
